(19) United States
(12) Patent Application Publication
(10) Pub. No.: US 2025/0350265 A1
(43) Pub. Date: Nov. 13, 2025

(54) ELECTRONIC DEVICE COMMUNICATING WITH EXTERNAL DEVICE, OPERATING METHOD OF ELECTRONIC DEVICE, AND ELECTRONIC SYSTEM INCLUDING ELECTRONIC DEVICES

(71) Applicant: SAMSUNG ELECTRONICS CO., LTD., Suwon-si (KR)

(72) Inventors: Tae Hyoung Kim, Seongnam-si (KR); Donghyun Yoon, Hwaseong-si (KR); Ikjin Jo, Suwon-si (KR); Myoungbo Kwak, Suwon-si (KR); Jueon Kim, Suwon-si (KR); Jaewoo Park, Suwon-si (KR); Junghwan Choi, Suwon-si (KR)

(73) Assignee: NANYANG TECHNOLOGICAL UNIVERSITY, Singapore (SG)

(21) Appl. No.: 18/924,695

(22) Filed: Oct. 23, 2024

(30) Foreign Application Priority Data
May 7, 2024 (KR) 10-2024-0059981

(51) Int. Cl. H03K 3/012; H03K 17/687

(52) U.S. Cl. CPC H03K 3/012; H03K 17/6871

(57) ABSTRACT

An electronic device is described which includes a transmitter, a first receiver, a second receiver, and an output circuit. The transmitter transmits a transmission signal to an external electronic device through a pad. The first receiver and the second receiver both receive a reception signal from the external electronic device through the pad. The output circuit determines whether data received through the reception signal belong to a high level, a middle level or a low level, based on an output of the first receiver and an output of the second receiver.

### CROSS-REFERENCE TO RELATED APPLICATION(S)

This application claims priority under 35 U.S.C. § 119 to Korean Patent Application No. 10-2024-0059981 filed on May 7, 2024, in the Korean Intellectual Property Office, the disclosures of which are incorporated by reference herein in their entireties.

### BACKGROUND

An electronic device may communicate with an external electronic device. For example, a memory device may communicate with a memory controller. To increase a communication speed of electronic devices, the frequency of signals which are communicated between the electronic devices is increasing. When the frequency of the communicated signals increases, the amount of power which the electronic devices consume for communication may increase.

When the frequency of a communication speed increases, the probability that an error occurs at a communication signal may increase. Accordingly, as the frequency of the communication signal increases, improved reliability may be required in a communication process.

Also, a mobile device such as a smartphone, a smart pad, or a smart watch operates based on a battery. Accordingly, electronic devices installed in the mobile device, for example, memory devices installed in the mobile device need to be implemented to operate with a low power. In particular, because the frequency of signals communicated between memory devices is expected to be continuously increasing, it is desired to reduce power consumption when electronic devices such as memory devices communicate with each other.

### SUMMARY

Implementations of the present disclosure provide an electronic device performing communication with a reduced power and improved reliability, an operating method of the electronic device, and an electronic system including electronic devices.

According to implementations, an electronic device includes a transmitter that transmits a transmission signal to an external electronic device through a pad, a first receiver that receives a reception signal from the external electronic device through the pad, a second receiver that receives the reception signal from the external electronic device through the pad, and an output circuit that determines data received through the reception signal, based on an output of the first receiver and an output of the second receiver.

According to implementations, an operating method of an electronic device which includes a first receiver and a second receiver and is configured to communicate with an external electronic device includes receiving a signal from the external electronic device, comparing, at the first receiver, the received signal with a first reference voltage, comparing, at the second receiver, the received signal with a second reference voltage, and determining whether data of the received signal correspond to any one of a high level, a low level, and a middle level, based on a comparison result of the first receiver and a comparison result of the second receiver.

According to implementations, an electronic device includes a transmitter that transmits a transmission signal to an external electronic device through a pad, a first receiver that receives a reception signal from the external electronic device through the pad, a second receiver that receives the reception signal from the external electronic device through the pad, and an output circuit that determines data received through the reception signal, based on an output of the first receiver and an output of the second receiver. Each of the first receiver and the second receiver includes a first transistor and a second transistor connected between a power node and a ground node, and a first resistor connected between a first node between the first transistor and the second transistor and the pad. A gate of the first transistor and a gate of the second transistor are connected to the pad, and a size of the first transistor is different from a size of the second transistor.

### BRIEF DESCRIPTION OF THE DRAWINGS

The above and other objects and features of the present disclosure will become apparent by describing in detail implementations thereof with reference to the accompanying drawings.

FIG. 1 illustrates an electronic system according to implementations of the present disclosure.

FIG. 2 illustrates a transceiver according to a first implementation of the present disclosure.

FIG. 3 illustrates an example of a signal in which a first electronic device and a second electronic device communicate.

FIG. 4 illustrates an example of a receiver of a first transceiver according to implementations of the present disclosure.

FIG. 5 illustrates an example of an output of a transmitter of a transceiver of a first electronic device, an input of a receiver of a transceiver of a second electronic device, and a voltage of a first node of a receiver of the transceiver of the second electronic device.

FIG. 6 illustrates a second transceiver according to a second implementation of the present disclosure.

FIG. 7 illustrates an operating method of a second transceiver according to implementations of the present disclosure.

FIG. 8 illustrates an example of a first receiver and a second receiver of a second transceiver according to implementations of the present disclosure.

FIG. 9 illustrates an example of a voltage of a first receiver and a voltage of a second node.

FIG. 10 illustrates an example of a voltage of a second receiver and a voltage of a third node.

FIG. 11 illustrates an example of a voltage of a second node and a voltage of a third node.

FIG. 12 illustrates an example of a first strong transistor according to implementations of the present disclosure.

FIG. 13 illustrates a reception resistor according to implementations of the present disclosure.

FIG. 14 illustrates an example of an electronic system according to another implementation of the present disclosure.

FIG. 15 illustrates an example of an electronic system according to another implementation of the present disclosure.

FIG. 16 illustrates an example of an electronic system according to another implementation of the present disclosure.

### DETAILED DESCRIPTION

Below, implementations of the present disclosure will be described in detail and clearly to such an extent that one of ordinary skill in the art may easily carry out the present disclosure.

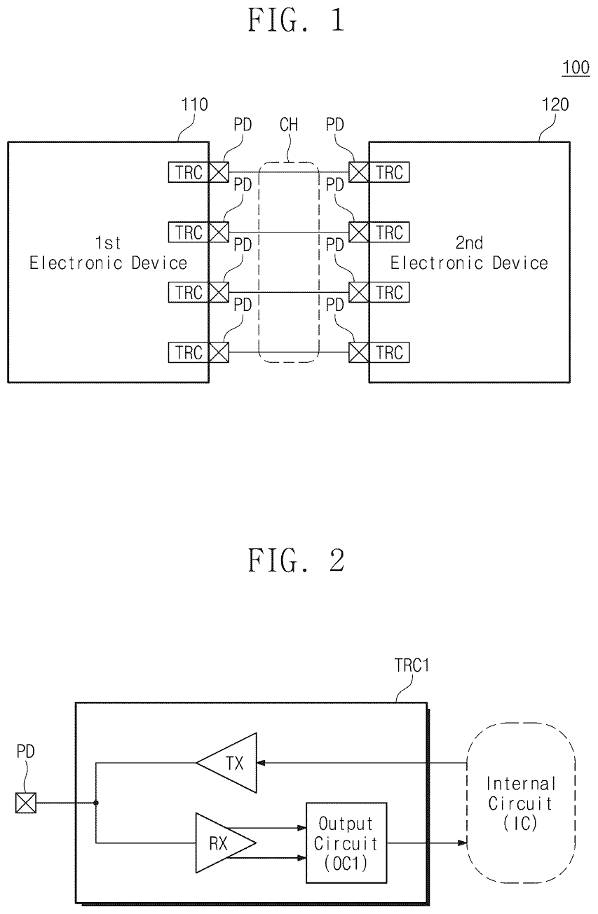

FIG. 1 illustrates an electronic system 100 according to implementations of the present disclosure. Referring to FIG. 1, the electronic system 100 may include a first electronic device 110 and a second electronic device 120. Each of the first electronic device 110 and the second electronic device 120 may include pads PD. Each of the first electronic device 110 and the second electronic device 120 may include transceivers TRC connected to the pads PD.

A channel CH may be provided between the first electronic device 110 and the second electronic device 120. For example, the channel CH may include signal lines connecting the pads PD of the first electronic device 110 and the pads PD of the second electronic device 120, respectively.

Each of the first electronic device 110 and the second electronic device 120 may transmit signals to the counterpart electronic device through the pads PD and the channel CH by controlling the transceivers TRC. Each of the first electronic device 110 and the second electronic device 120 may receive signals input to the pads PD from the counterpart electronic device through the channel CH, by using the transceivers TRC.

FIG. 2 illustrates a first transceiver TRC1 according to a first implementation of the present disclosure. In implementations, the first transceiver TRC1 may correspond to the transceivers TRC of FIG. 1.

Referring to FIGS. 1 and 2, the first transceiver TRC1 may be connected between the corresponding pad PD and an internal circuit IC. The internal circuit IC may include various components and may be configured to perform intended functions of the first electronic device 110 or the second electronic device 120 and to communicate with an external device by using the first transceiver TRC1.

The first transceiver TRC1 may include a transmitter TX, a receiver RX, and a first output circuit OC1. The transmitter TX may convert data transferred from the internal circuit IC into a communication signal and may transmit the communication signal to an external electronic device through the pad PD. The receiver RX may convert the communication signal received through the corresponding pad PD into two signals. The first output circuit OC1 may determine data of the communication signal received through the corresponding pad PD, based on the two signals transferred from the receiver RX. The first output circuit OC1 may transfer the determined data to the internal circuit IC.

For example, a signal which the first electronic device 110 or the second electronic device 120 communicates through the pads PD may be based on the pulse amplitude modulation 3 (PAM3). The PAM3 signal may have one of three values at a time. For example, the PAM3 signal may have a value corresponding to one of “−1”, “0”, and “1”. In implementations, “−1”, “0”, and “1” may respectively correspond to a low level, a middle level, and a high level. The transmitter TX may receive a signal indicating one of the low level, the middle level, and the high level from the internal circuit IC.

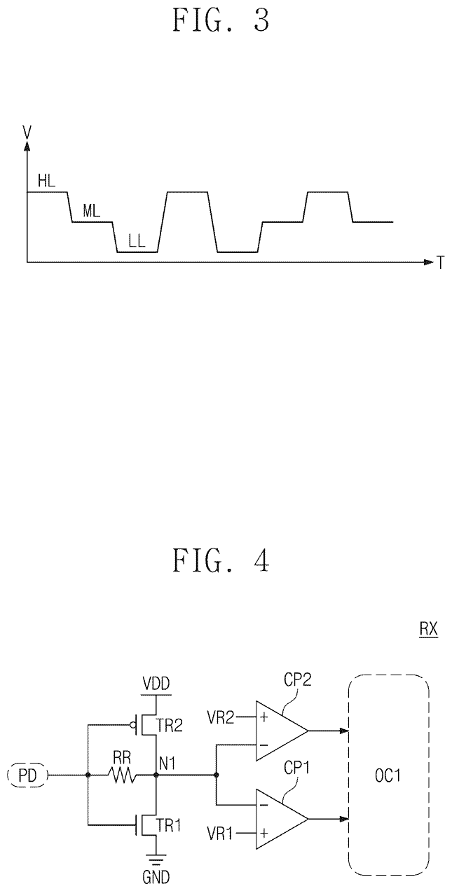

FIG. 3 illustrates an example of a signal in which the first electronic device 110 and the second electronic device 120 communicate. In FIG. 3, the horizontal axis represents a time “T”, and the vertical axis represents a voltage “V”. Referring to FIGS. 1, 2, and 3, the first electronic device 110 and the second electronic device 120 may communicate a signal with one of a high level HL, a low level LL, and a middle level ML.

FIG. 4 illustrates an example of the receiver RX of the first transceiver TRC1 according to implementations of the present disclosure. Referring to FIGS. 1, 2, and 4, the receiver RX may include a first transistor TR1, a second transistor TR2, a reception resistor RR, a first comparator CP1, and a second comparator CP2.

The first transistor TR1 may include a gate connected to the corresponding pad PD, a first terminal connected to a first node N1 between the first transistor TR1 and the second transistor TR2, and a second terminal connected to a ground node to which a ground voltage GND is applied. In implementations, the first transistor TR1 may be implemented with an NMOS transistor.

The second transistor TR2 may include a gate connected to the corresponding pad PD, a first terminal connected to a power node to which a power supply voltage VDD is applied, and a second terminal connected to the first node N1. In implementations, the second transistor TR2 may be implemented with a PMOS transistor.

The reception resistor RR may be connected between the corresponding pad PD and the first node N1. In implementations, the first transistor TR1, the second transistor TR2, and the reception resistor RR may be implemented with an inverter-based transimpedance amplifier (TIA).

When a signal received through the corresponding pad PD is at the high level, a voltage of the first node N1 may be at the low level. When a signal received through the corresponding pad PD is at the low level, a voltage of the first node N1 may be at the high level. When a signal received through the corresponding pad PD is at the middle level, a voltage of the first node N1 may be at the middle level.

The first comparator CP1 may receive a first reference voltage VR1 as a positive input and may receive the voltage of the first node N1 as a negative input. When the first reference voltage VR1 is greater than the voltage of the first node N1, the first comparator CP1 may output the high level. When the first reference voltage VR1 is equal to or smaller than the voltage of the first node N1, the first comparator CP1 may output the low level.

The second comparator CP2 may receive a second reference voltage VR2 as a positive input and may receive the voltage of the first node N1 as a negative input. When the second reference voltage VR2 is greater than the voltage of the first node N1, the second comparator CP2 may output the high level. When the second reference voltage VR2 is equal to or smaller than the voltage of the first node N1, the second comparator CP2 may output the low level.

The output of the first comparator CP1 and the output of the second comparator CP2 may be transferred to the internal circuit IC as an output of the receiver RX.

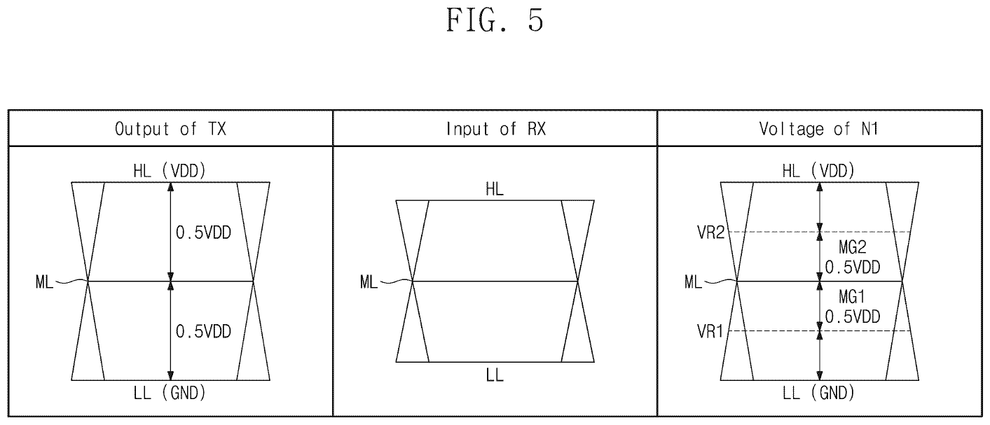

FIG. 5 illustrates an example of an output of the transmitter TX of the transceiver TRC of the first electronic device 110, an input of the receiver RX of the transceiver TRC of the second electronic device 120, and a voltage of the first node N1 of the receiver RX of the transceiver TRC of the second electronic device 120. In implementations, an example of eye diagrams of the output of the transmitter TX of the transceiver TRC of the first electronic device 110, the input of the receiver RX of the transceiver TRC of the second electronic device 120, and the voltage of the first node N1 of the receiver RX of the transceiver TRC of the second electronic device 120 are illustrated in FIG. 5.

Referring to FIGS. 1, 2, 4, and 5, the output of the transmitter TX of the transceiver TRC of the first electronic device 110 may be of one of the high level HL, the low level LL, and the middle level ML. The high level HL may correspond to the power supply voltage VDD. The low level LL may correspond the ground voltage GND. The middle level ML may have a level between the power supply voltage VDD and the ground voltage GND. For example, the middle level ML may correspond to 0.5VDD.

The output of the transmitter TX of the transceiver TRC of the first electronic device 110 may be transferred through the channel CH as the input of the receiver RX of the transceiver TRC of the second electronic device 120. In implementations, the output of the transmitter TX of the transceiver TRC may be attenuated due to the parasitic resistance of the channel CH. For example, the low level LL of the input of the receiver RX of the transceiver TRC of the second electronic device 120 may be higher than the low level LL of the input of the transmitter TX of the transceiver TRC of the first electronic device 110. The high level HL of the input of the receiver RX of the transceiver TRC of the second electronic device 120 may be lower than the high level HL of the output of the transmitter TX of the transceiver TRC of the first electronic device 110.

When the input of the receiver RX is at the high level HL, the voltage of the first node N1 may be at the low level LL. When the input of the receiver RX is at the low level, the voltage of the first node N1 may be at the high level HL. When the input of the receiver RX is at the middle level ML, the voltage of the first node N1 may be at the middle level ML. The voltage of the first node N1 may be transferred to the first comparator CP1 and the second comparator CP2.

The first comparator CP1 may compare the first reference voltage VR1 and the voltage of the first node N1. For example, the first reference voltage VR1 may have a level between the low level LL corresponding to the ground voltage GND and the middle level ML corresponding to 0.5VDD. When the first reference voltage VR1 is greater than the voltage of the first node N1, that is, when the voltage of the first node N1 corresponds to the low level LL, the first comparator CP1 may output the logic high level (e.g., not the high level of the PAM3 but the high level of the binary logic operation). When the first reference voltage VR1 is equal to or smaller than the voltage of the first node N1, that is, when the voltage of the first node N1 corresponds to the middle level ML or the high level HL, the first comparator CP1 may output the logic low level (e.g., not the low level of the PAM3 but the low level of the binary logic operation). That is, when a signal received by the receiver RX is at the high level HL, the first comparator CP1 may output the logic high level.

The second comparator CP2 may compare the second reference voltage VR2 and the voltage of the first node N1. For example, the second reference voltage VR2 may have a level between the high level HL corresponding to the power supply voltage VDD and the middle level ML corresponding to 0.5VDD. When the second reference voltage VR2 is equal to or smaller than the voltage of the first node N1, that is, when the voltage of the first node N1 corresponds to the high level HL, the second comparator CP2 may output the logic low level. When the second reference voltage VR2 is greater the voltage of the first node N1, that is, when the voltage of the first node N1 corresponds to the middle level ML or the low level LL, the second comparator CP2 may output the logic high level. That is, when a signal received by the receiver RX is at the low level LL, the second comparator CP2 may output the logic low level.

The first output circuit OC1 may receive the output of the first comparator CP1 and the output of the second comparator CP2. When the outputs of the first comparator CP1 and the second comparator CP2 are at the logic high level, the first output circuit OC1 may determine that the low level LL is received by the receiver RX. When the outputs of the first comparator CP1 and the second comparator CP2 are at the logic low level, the first output circuit OC1 may determine that the high level HL is received by the receiver RX. When the logic low level is received from one of the first comparator CP1 and the second comparator CP2 and the logic high level is received from the other comparator, the first output circuit OC1 may determine that the middle level ML is received by the receiver RX.

The operation in which the first comparator CP1 determines the middle level ML and the low level LL may have a first margin MG1. For example, the first margin MG1 may indicate a margin range in which the first comparator CP1 normally determines the low level LL and the middle level ML without an error even though the unintended change in the first reference voltage VR1 or the voltage of the first node N1 is made (e.g., due to the noise or interference). For example, the first margin MG1 may be 0.5VDD.

Likewise, the operation in which the second comparator CP2 determines the middle level ML and the high level HL may have a second margin MG2. For example, the second margin MG2 may indicate a margin range in which the second comparator CP2 determines normally the high level HL and the middle level ML without an error even though the unintended change in the second reference voltage VR2 or the voltage of the first node N1 is made (e.g., due to the noise or interference). For example, the second margin MG2 may be 0.5VDD.

As the first electronic device 110 or the second electronic device 120 is implemented to operate with a lower power, the level of the power supply voltage VDD may decrease. Accordingly, the first margin MG1 of the first comparator CP1 and the second margin MG2 of the second comparator CP2 may decrease. Accordingly, the reliability of the first electronic device 110 or the second electronic device 120 may be reduced.

When the middle level ML is received by the receiver RX, both the first transistor TR1 and the second transistor TR2 may be turned on. As both the first transistor TR1 and the second transistor TR2 are turned on, a constant current may flow between the ground node to which the ground voltage GND is applied and the power node to which the power supply voltage VDD is applied. The constant current may increase the power consumption of the first electronic device 110 or the second electronic device 120 and may hinder the implementation of the low-power electronic device 110 or 120.

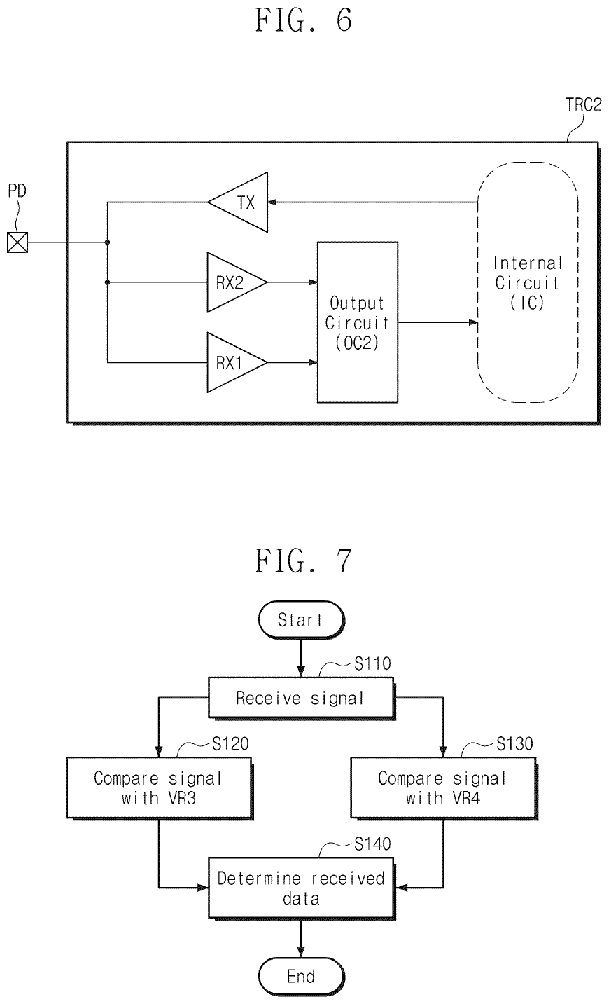

FIG. 6 illustrates a second transceiver TRC2 according to a second implementation of the present disclosure. In implementations, the second transceiver TRC2 may correspond to the transceivers TRC of FIG. 1.

Referring to FIGS. 1 and 6, the second transceiver TRC2 may be connected between the corresponding pad PD and the internal circuit IC. The internal circuit IC may include various components and may be configured to perform intended functions of the first electronic device 110 or the second electronic device 120 and to communicate with an external device by using the second transceiver TRC2.

The second transceiver TRC2 may include a transmitter TX, a first receiver RX1, a second receiver RX2, and a second output circuit OC2. The transmitter TX may convert data transferred from the internal circuit IC into a communication signal and may transmit the communication signal to an external electronic device through the pad PD.

The first receiver RX1 and the second receiver RX2 may receive the communication signal input to the corresponding pad PD in common. The first receiver RX1 may perform first comparison for the communication signal received through the corresponding pad PD and may transmit a result of the first comparison to the second output circuit OC2. The second receiver RX2 may perform second comparison for the communication signal received through the corresponding pad PD and may transmit a result of the second comparison to the second output circuit OC2.

The second output circuit OC2 may determine data of the communication signal received through the corresponding pad PD, based on the signal received from the first receiver RX1 and the signal received from the second receiver RX2. The second output circuit OC2 may transfer the determined data to the internal circuit IC.

For example, a signal which the first electronic device 110 or the second electronic device 120 communicates through the pads PD may be based on the pulse amplitude modulation 3 (PAM3). The PAM3 signal may have one of three values at a time. For example, the PAM3 signal may have a value corresponding to one of “−1”, “0”, and “1”. In implementations, “−1”, “0”, and “1” may respectively correspond to a low level, a middle level, and a high level. A transmission buffer TB may receive a signal indicating one of the low level, the middle level, and the high level from the internal circuit IC. The PAM3-based signal may be communicated as illustrated in FIG. 3.

FIG. 7 illustrates an operating method of the second transceiver TRC2 according to implementations of the present disclosure. Referring to FIGS. 1, 6, and 7, in operation S110, the second transceiver TRC2 may receive a signal. For example, the first receiver RX1 and the second receiver RX2 of the second transceiver TRC2 may receive the communication signal through the corresponding pad PD.

In operation S120, the first receiver RX1 of the second electronic device 120 may compare the signal and a third reference voltage VR3. For example, the first receiver RX1 may amplify the received communication signal and may perform first comparison for comparing the amplified signal and the third reference voltage VR3.

In operation S130, the second receiver RX2 of the second electronic device 120 may compare the signal and a fourth reference voltage VR4. For example, the second receiver RX2 may amplify the received communication signal and may perform second comparison for comparing the amplified signal and the fourth reference voltage VR4. In implementations, operation S120 and operation S130 may be performed in parallel.

In operation S140, the second output circuit OC2 of the second transceiver TRC2 may determine the received data. For example, the second output circuit OC2 may determine data of the communication signal received by the second transceiver TRC2, based on the signal received from the first receiver RX1, that is, a result of the first comparison and the signal received from the second receiver RX2, that is, a result of the second comparison. For example, the second output circuit OC2 may determine whether the data of the signal received by the second transceiver TRC2 correspond to the high level HL, the low level LL, or the middle level ML.

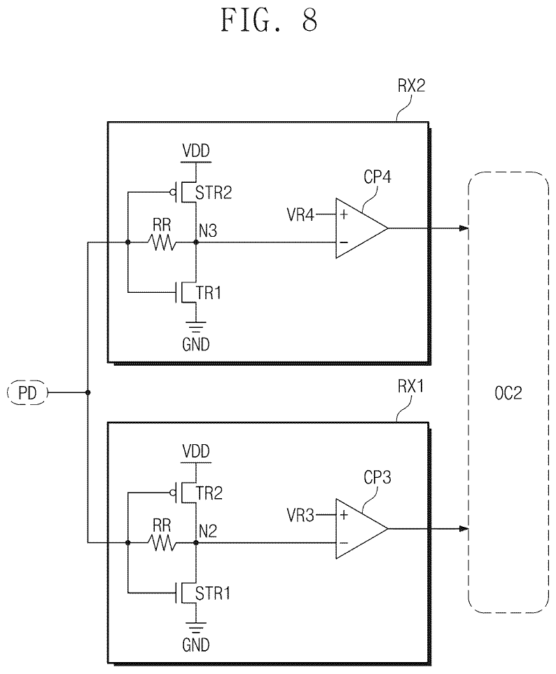

FIG. 8 illustrates an example of the first receiver RX1 and the second receiver RX2 of the second transceiver TRC2 according to implementations of the present disclosure. Referring to FIGS. 1, 6, and 8, the first receiver RX1 may include a first strong transistor STR1, a second transistor TR2, a reception resistor RR, and a third comparator CP3.

The first strong transistor STR1 may include a gate connected to the corresponding pad PD, a first terminal connected to a second node N2 between the first strong transistor STR1 and the second transistor TR2, and a second terminal connected to the ground node to which the ground voltage GND is applied. In implementations, the first strong transistor STR1 may be implemented with an NMOS transistor.

The second transistor TR2 may include a gate connected to the corresponding pad PD, a first terminal connected to the power node to which the power supply voltage VDD is applied, and a second terminal connected to the second node N2. In implementations, the second transistor TR2 may be implemented with a PMOS transistor.

The reception resistor RR may be connected between the corresponding pad PD and the node of the internal circuit IC. In implementations, the first strong transistor STR1, the second transistor TR2, and the reception resistor RR may be implemented with an inverter-based TIA.

When the signal received through the corresponding pad PD is at the high level, a voltage of the second node N2 may be of the low level. When the signal received through the corresponding pad PD is at the low level, a voltage of the second node N2 may be of the high level. When the signal received through the corresponding pad PD is at the middle level, a voltage of the second node N2 may be of the middle level.

In implementations, the size of the first strong transistor STR1 may be larger than the size of the second transistor TR2. The size of a transistor may correspond to the width of the channel of the transistor. The size of the transistor may correspond to the amount of current flowing through the channel of the transistor when the same voltages are respectively applied to the gate and terminals of the transistor. As the size of the transistor becomes larger, the amount of current flowing through the transistor may increase. As the size of the transistor decreases, the amount of current flowing through the transistor may decrease.

That is, when the same voltage is applied to the gate of the first strong transistor STR1 and the gate of the second transistor TR2 through the corresponding pad PD, the amount of current which the first strong transistor STR1 drains from the second node N2 to the ground node to which the ground voltage GND is applied may be greater than the amount of current which the second transistor TR2 supplies to the second node N2 from the power node to which the power supply voltage VDD is supplied. Accordingly, when the signal of the middle level ML is received through the corresponding pad PD, the voltage of the second node N2 may be lower than 0.5VDD.

The third comparator CP3 may receive the third reference voltage VR3 as a positive input and may receive the voltage of the second node N2 as a negative input. When the third reference voltage VR3 is greater than the voltage of the second node N2, the third comparator CP3 may output the high level. When the third reference voltage VR3 is equal to or smaller than the voltage of the second node N2, the third comparator CP3 may output the low level. The output of the third comparator CP3 may be transferred to the second output circuit OC2 as the output of the first receiver RX1.

The second receiver RX2 may include a first transistor TR1, a second strong transistor STR2, a reception resistor RR, and a fourth comparator CP4.

The first transistor TR1 may include a gate connected to the corresponding pad PD, a first terminal connected to a third node N3 between the first transistor TR1 and the second strong transistor STR2, and a second terminal connected to the ground node to which the ground voltage GND is applied. In implementations, the first transistor TR1 may be implemented with an NMOS transistor.

The second strong transistor STR2 may include a gate connected to the corresponding pad PD, a first terminal connected to the power node to which the power supply voltage VDD is applied, and a second terminal connected to the third node N3. In implementations, the second strong transistor STR2 may be implemented with a PMOS transistor.

The reception resistor RR may be connected between the corresponding pad PD and the node of the internal circuit IC. In implementations, the first transistor TR1, the second strong transistor STR2, and the reception resistor RR may be implemented with an inverter-based TIA.

When the signal received through the corresponding pad PD is at the high level, a voltage of the third node N3 may be of the low level. When the signal received through the corresponding pad PD is at the low level, a voltage of the third node N3 may be of the high level. When the signal received through the corresponding pad PD is at the middle level, a voltage of the third node N3 may be of the middle level.

In implementations, the size of the second strong transistor STR2 may be larger than the size of the first transistor TR1. That is, when the same voltage is applied to the gate of the first transistor TR1 and the gate of the second strong transistor STR2 through the corresponding pad PD, the amount of current which the first transistor TR1 drains from the third node N3 to the ground node to which the ground voltage GND is applied may be smaller than the amount of current which the second strong transistor STR2 supplies to the third node N3 from the power node to which the power supply voltage VDD is supplied. Accordingly, when the signal of the middle level ML is received through the corresponding pad PD, the voltage of the third node N3 may be higher than 0.5VDD.

The fourth comparator CP4 may receive the fourth reference voltage VR4 as a positive input and may receive the voltage of the third node N3 as a negative input. When the fourth reference voltage VR4 is greater than the voltage of the third node N3, the fourth comparator CP4 may output the high level. When the fourth reference voltage VR4 is equal to or smaller than the voltage of the third node N3, the fourth comparator CP4 may output the low level. The output of the fourth comparator CP4 may be transferred to the second output circuit OC2 as the output of the second receiver RX2.

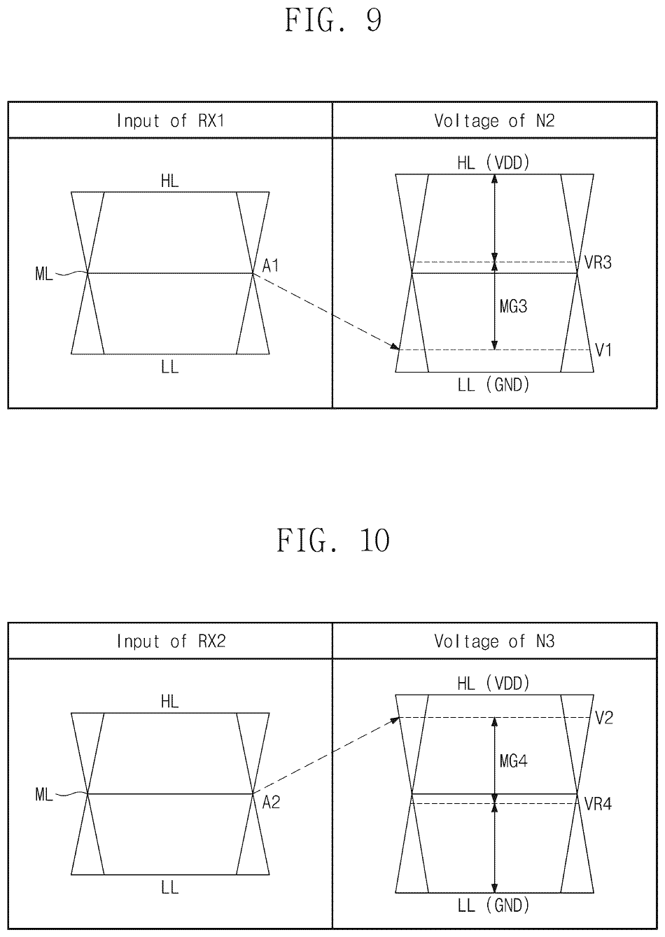

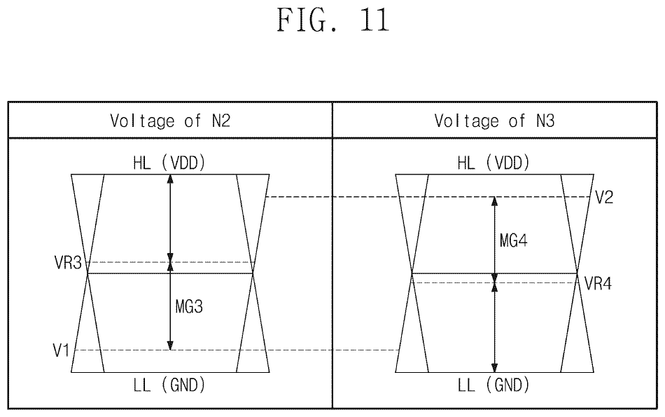

FIG. 9 illustrates an example of an input of the first receiver RX1 and a voltage of the second node N2. In implementations, eye diagrams of the input of the first receiver RX1 and the voltage of the second node N2 are illustrated.

Referring to FIGS. 1, 6, 8, and 9, the input of the first receiver RX1 may be in the shape of being attenuated as described with reference to FIG. 5.

When the attenuated low level LL is received by the first receiver RX1, the voltage of the second node N2 may be of the high level of the power supply voltage VDD. When the attenuated high level HL is received by the first receiver RX1, the voltage of the second node N2 may be of the low level LL of the ground voltage GND.

When the middle level ML is received by the first receiver RX1, as described with reference to FIG. 8, the amount of current which the first strong transistor STR1 drains from the second node N2 may be greater than the amount of current which the second transistor TR2 supplies to the second node N2. Accordingly, when the middle level ML is received by the first receiver RX1, as marked by a first arrow A1, the voltage of the second node N2 may be a first voltage V1 lower than 0.5VDD.

The third comparator CP3 may receive the signal having the high level HL of the power supply voltage VDD, the low level LL of the ground voltage GND, or the middle level ML of the first voltage V1. The third reference voltage VR3 input to the third comparator CP3 may have a level between the power supply voltage VDD of the high level HL and the first voltage V1 of the middle level ML. Accordingly, a third margin MG3 with which the third comparator CP3 determines the high level HL and the middle level ML may be greater than 0.5VDD.

Also, when 0.5VDD is formed at the first node N1 when the middle level ML is received by the receiver RX of FIG. 4, the description is given as a constant current flows through the first transistor TR1 and the second transistor TR2. However, when the middle level ML is received by the first receiver RX1, a voltage formed at the second node N2 of the first receiver RX1 may be not 0.5VDD but the first voltage V1 may be closer to the ground voltage GND. Accordingly, a constant current flowing through the first strong transistor STR1 and the second transistor TR2 is reduced, and the power consumption of the first receiver RX1 is reduced.

FIG. 10 illustrates an example of an input of the second receiver RX2 and a voltage of the third node N3. In implementations, eye diagrams of the input of the second receiver RX2 and the voltage of the third node N3 are illustrated.

Referring to FIGS. 1, 6, 8, and 10, the input of the second receiver RX2 may be in the shape of being attenuated as described with reference to FIG. 5.

When the attenuated low level LL is received by the second receiver RX2, the voltage of the third node N3 may be of the high level of the power supply voltage VDD. When the attenuated high level HL is received by the second receiver RX2, the voltage of the third node N3 may be of the low level LL of the ground voltage GND.

When the middle level ML is received by the second receiver RX2, as described with reference to FIG. 8, the amount of current which the second strong transistor STR2 supplies to the third node N3 may be greater than the amount of current which the first transistor TR1 drains from the third node N3. Accordingly, when the middle level ML is received by the second receiver RX2, as marked by a second arrow A2, the voltage of the third node N3 may be a second voltage V2 higher than 0.5VDD.

The fourth comparator CP4 may receive the signal having the high level HL of the power supply voltage VDD, the low level LL of the ground voltage GND, or the middle level ML of the second voltage V2. The fourth reference voltage VR4 input to the fourth comparator CP4 may have a level between the second voltage V2 of the middle level ML and the ground voltage GND of the low level LL. Accordingly, a fourth margin MG4 with which the fourth comparator CP4 determines the low level LL and the middle level ML may be greater than 0.5VDD.

Also, when 0.5VDD is formed at the first node N1 when the middle level ML is received by the receiver RX of FIG. 4, the description is given as a constant current flows through the first transistor TR1 and the second transistor TR2. However, when the middle level ML is received by the second receiver RX2, a voltage formed at the third node N3 of the second receiver RX2 may be not 0.5VDD but the second voltage V2 close to the power supply voltage VDD. Accordingly, a constant current flowing through the first transistor TR1 and the second strong transistor STR2 is reduced, and the power consumption of the second receiver RX2 is reduced.

FIG. 11 illustrates an example of a voltage of the second node N2 and a voltage of the third node N3. Referring to FIGS. 1, 8, and 11, when the signal received through the corresponding pad PD is at the middle level ML, the voltage of the second node N2 may be the first voltage V1. When the signal received through the corresponding pad PD is at the middle level ML, the voltage of the third node N3 may be the second voltage V2. Accordingly, when the voltage of the middle level ML belongs to a range between the first voltage V1 and the second voltage V2, at least one of the third comparator CP3 and the fourth comparator CP4 may identify that data of the signal received through the corresponding pad PD correspond to the middle level ML.

According to implementations of the present disclosure, when the third margin MG3 with which the third comparator CP3 identifies the middle level ML and the high level HL exceeds 0.5VDD, the fourth margin MG4 with which the fourth comparator CP4 identifies the middle level ML and the low level LL also exceeds 0.5VDD. Also, the range in which the third comparator CP3 identifies the middle level ML and the range in which the fourth comparator CP4 identifies the middle level ML overlap each other, and thus, the middle level ML may be identified with higher reliability.

Accordingly, the reliability with which the first receiver RX1 and the second receiver RX2 identify the middle level ML is improved. Also, the reliability of the second transceiver TRC2 including the first receiver RX1 and the second receiver RX2, the first and second electronic devices 110 and 120 each including the second transceiver TRC2 may be improved.

In the examples of FIGS. 8, 9, 10, and 11, when both the output of the third comparator CP3 and the output of the fourth comparator CP4 are at the logic high level, the second output circuit OC2 may determine that both the voltage of the second node N2 and the voltage of the third node N3 are at the high level HL. Accordingly, the second output circuit OC2 may determine that the low level LL is received by the second transceiver TRC2 through the corresponding pad PD.

When the output of the third comparator CP3 is at the logic high level but the output of the fourth comparator CP4 is at the logic low level, the second output circuit OC2 may identify that the voltage of the second node N2 is of the high level HL but the voltage of the third node N3 is of the middle level ML or the low level LL. Accordingly, the second output circuit OC2 may determine that the middle level ML is received by the second transceiver TRC2 through the corresponding pad PD.

When the output of the third comparator CP3 is at the logic low level but the output of the fourth comparator CP4 is at the logic high level, the second output circuit OC2 may identify that the voltage of the second node N2 is of the high level HL or the middle level ML but the voltage of the third node N3 is of the low level LL. Accordingly, the second output circuit OC2 may determine that the middle level ML is received by the second transceiver TRC2 through the corresponding pad PD.

When both the output of the third comparator CP3 and the output of the fourth comparator CP4 are at the logic low level, the second output circuit OC2 may determine that both the voltage of the second node N2 and the voltage of the third node N3 are of the low level LL. Accordingly, the second output circuit OC2 may determine that the high level HL is received by the second transceiver TRC2 through the corresponding pad PD.

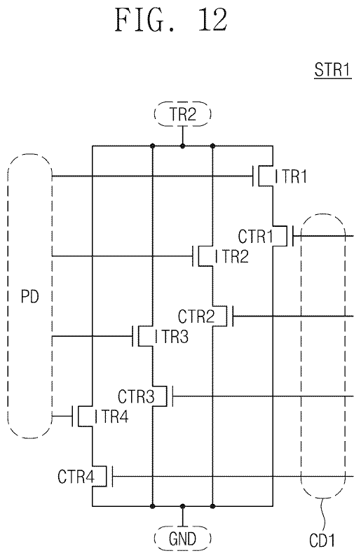

FIG. 12 illustrates an example of the first strong transistor STR1 according to implementations of the present disclosure. Referring to FIGS. 8 and 12, the first strong transistor STR1 may include a first inverting transistor ITR1, a second inverting transistor ITR2, a third inverting transistor ITR3, a fourth inverting transistor ITR4, a first calibration transistor CTR1, a second calibration transistor CTR2, a third calibration transistor CTR3, and a fourth calibration transistor CTR4.

The first inverting transistor ITR1 and the first calibration transistor CTR1 may form a pair and may be connected between the second transistor TR2 and the ground node to which the ground voltage GND is applied. The second inverting transistor ITR2 and the second calibration transistor CTR2 may form a pair and may be connected between the second transistor TR2 and the ground node to be parallel to the pair of first inverting transistor ITR1 and first calibration transistor CTR1.

The third inverting transistor ITR3 and the third calibration transistor CTR3 may form a pair and may be connected between the second transistor TR2 and the ground node to be parallel to the pair of first inverting transistor ITR1 and first calibration transistor CTR1 and the pair of second inverting transistor ITR2 and second calibration transistor CTR2.

The fourth inverting transistor ITR4 and the fourth calibration transistor CTR4 may form a pair and may be connected between the second transistor TR2 and the ground node to be parallel to the pair of first inverting transistor ITR1 and first calibration transistor CTR1, the pair of second inverting transistor ITR2 and second calibration transistor CTR2, and the pair of third inverting transistor ITR3 and third calibration transistor CTR3.

Gates of the first inverting transistor ITR1, the second inverting transistor ITR2, the third inverting transistor ITR3, and the fourth inverting transistor ITR4 may be connected in common to the corresponding pad PD. Gates of the first calibration transistor CTR1, the second calibration transistor CTR2, the third calibration transistor CTR3, and the fourth calibration transistor CTR4 may be controlled by a first code CD1.

An inverting transistor corresponding to a calibration transistor turned off by the first code CD1 may not form a current path between the second transistor TR2 and the ground node regardless of a signal of the corresponding pad PD. The inverting transistor corresponding to the calibration transistor turned on by the first code CD1 may selectively form a current path between the second transistor TR2 and the ground node in response to the signal of the corresponding pad PD. That is, the first code CD1 may adjust the size of the first strong transistor STR1.

In implementations, the first strong transistor STR1 is illustrated as including four transistor pairs. However, the number of pairs of transistors included in the first strong transistor STR1 is not limited.

In implementations, a configuration and an operation of the second strong transistor STR2 may be the same as those of the first strong transistor STR1 except that the second transistor TR2 is replaced with the power supply voltage VDD, the ground voltage GND is replaced with the first transistor TR1, and NMOS transistors are replaced with PMOS transistors. Thus, additional description will be omitted to avoid redundancy.

In implementations, the size of the first transistor TR1 and the size of the second transistor TR2 may also be adjusted as described with reference to FIG. 12.

FIG. 13 illustrates the reception resistor RR according to implementations of the present disclosure. Referring to FIGS. 1, 8, and 13, the reception resistor RR may include a third transistor TR3, a fourth transistor TR4, a fifth transistor TR5, a sixth transistor TR6, a first resistor R1, a second resistor R2, a third resistor R3, and a fourth resistor R4.

The third transistor TR3 and the first resistor R1 may form a pair and may be connected between the corresponding pad PD and the second or third node N2 or N3. The fourth transistor TR4 and the second resistor R2 may form a pair and may be connected between the corresponding pad PD and the second or third node N2 or N3 to be parallel to the pair of third transistor TR3 and first resistor R1.

The fifth transistor TR5 and the third resistor R3 may form a pair and may be connected between the corresponding pad PD and the second or third node N2 or N3 to be parallel to the pair of third transistor TR3 and first resistor R1 and the pair of fourth transistor TR4 and the second resistor R2.

The sixth transistor TR6 and the fourth resistor R4 may form a pair and may be connected between the corresponding pad PD and the second or third node N2 or N3 to be parallel to the pair of third transistor TR3 and first resistor R1, the pair of fourth transistor TR4 and the second resistor R2, and the pair of fifth transistor TR5 and third resistor R3.

The third transistor TR3, the fourth transistor TR4, the fifth transistor TR5, and the sixth transistor TR6 may be turned on or turned off by a second code CD2.

A total resistance value between the corresponding pad PD and the second or third node N2 or N3 may be determined by the second code CD2. A resistance value of a resistor connected to a transistor, which is turned on by the second code CD2, from among the third transistor TR3, the fourth transistor TR4, the fifth transistor TR5, and the sixth transistor TR6 may be applied to the total resistance value between the corresponding pad PD and the second or third node N2 or N3. A resistance value of a resistor connected to a transistor, which is turned off by the second code CD2, from among the third transistor TR3, the fourth transistor TR4, the fifth transistor TR5, and the sixth transistor TR6 may not be applied to the total resistance value between the corresponding pad PD and the second or third node N2 or N3.

In implementations, the reception resistor RR is illustrated as including four transistor and resistor pairs. However, the number of transistor and resistor pairs included in the reception resistor RR is not limited thereto.

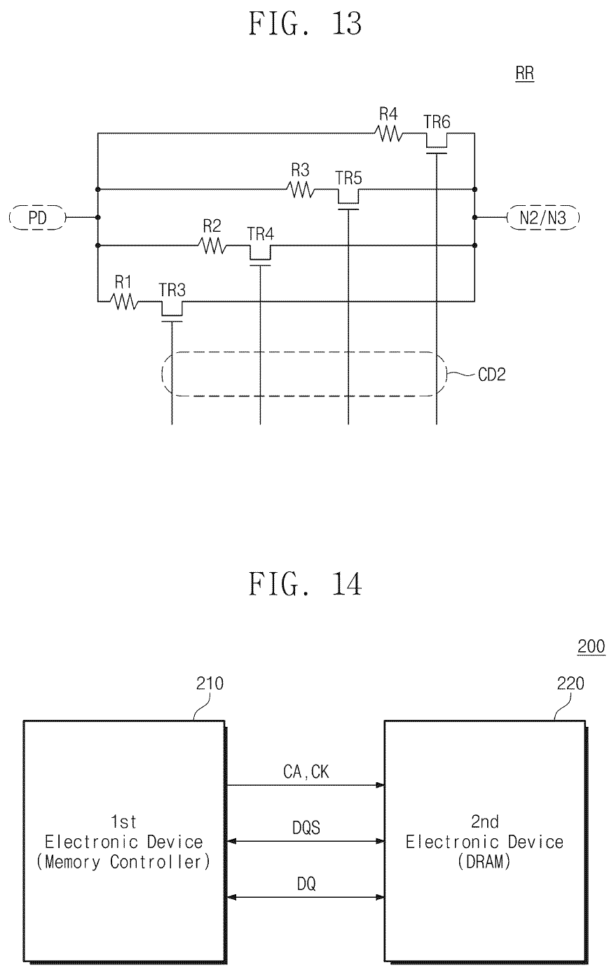

FIG. 14 illustrates an electronic system 200 according to implementations of the present disclosure. Referring to FIG. 14, the electronic system 200 may include a first electronic device 210 and a second electronic device 220. The first electronic device 210 and the second electronic device 220 may respectively correspond to the first electronic device 110 and the second electronic device 120 described with reference to FIGS. 1 to 13.

In implementations, the first electronic device 210 may be a memory controller. The second electronic device 220 may be a memory device, for example, a dynamic random access memory (DRAM) device. The first electronic device 210 and the second electronic device 220 may communicate based on the double data rate (DDR) standard.

The first electronic device 210 may provide a command and address signals CA and a clock signal CK to the second electronic device 220. The first electronic device 210 and the second electronic device 220 may communicate a data strobe signal DQS. For example, the data strobe signal DQS may include a write data strobe signal which the first electronic device 210 generates so as to be transmitted to the second electronic device 220 and a read data strobe signal which the second electronic device 220 generates from the clock signal CK so as to be transmitted to the first electronic device 210.

The first electronic device 210 and the second electronic device 220 may communicate a data signal DQ in synchronization with the data strobe signal DQS. For example, the first electronic device 210 may transmit the data strobe signal DQS and the data signal DQ to the second electronic device 220. The second electronic device 220 may capture the data signal DQ in synchronization with the data strobe signal DQS. The second electronic device 220 may transmit the data strobe signal DQS and the data signal DQ to the first electronic device 210. The first electronic device 210 may capture the data signal DQ in synchronization with the data strobe signal DQS.

In implementations, the pads PD described with reference to FIGS. 1 to 13 may be pads for transmitting the data signal DQ. The transceivers TRC described with reference to FIGS. 1 to 13 may transmit and receive the data signal DQ based on the PAM3. Each of the transceivers TRC may include the first receiver RX1 and the second receiver RX2 extending a margin by performing level conversion for the middle level ML by using strong transistors.

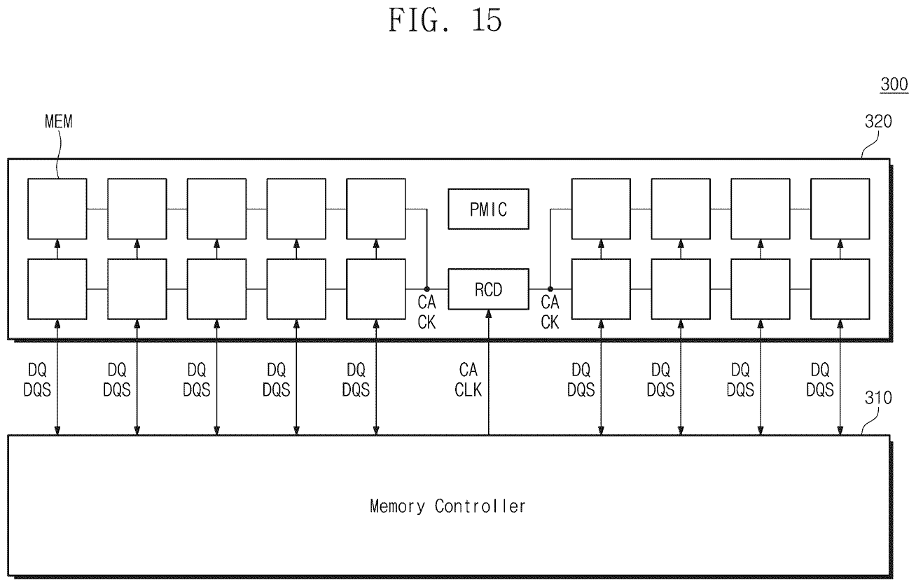

FIG. 15 illustrates an electronic system 300 according to some implementations of the present disclosure. Referring to FIG. 15, the electronic system 300 may include a first electronic device 310 and a second electronic device 320. The first electronic device 310 and the second electronic device 320 may respectively correspond to the first electronic device 110 and the second electronic device 120 described with reference to FIGS. 1 to 13.

In implementations, the first electronic device 310 may be a memory controller. The second electronic device 320 may be a memory module. The first electronic device 310 and the second electronic device 320 may communicate with each other based on the dual in-line memory module (DIMM), a registered DIMM (RDIMM), or a load reduced DIMM (LRDIMM) standard.

The second electronic device 320 may include a register clock driver RCD, a power management integrated circuit (IC) PMIC, and memory devices MEM. The memory devices MEM may include, for example, DRAM devices.

The first electronic device 310 may provide the command and address signals CA and the clock signal CK to the register clock driver RCD of the second electronic device 320. The register clock driver RCD may provide the command and address signals CA and the clock signal CK in common to the memory devices MEM. The first electronic device 310 may supply a power to the power management IC PMIC of the second electronic device 320. The power management IC PMIC may supply the power to the register clock driver RCD and the memory devices MEM of the second electronic device 320.

The first electronic device 310 and the memory devices MEM of the second electronic device 320 may communicate the data strobe signal DQS. For example, the data strobe signal DQS may include a write data strobe signal which the first electronic device 310 generates so as to be transmitted to the memory devices MEM of the second electronic device 320 and a read data strobe signal which each of the memory devices MEM of the second electronic device 320 generates from the clock signal CK so as to be transmitted to the first electronic device 310.

The first electronic device 310 and the memory devices MEM of the second electronic device 320 may communicate the data signal DQ in synchronization with the data strobe signal DQS. For example, the first electronic device 310 may transmit the data strobe signal DQS and the data signal DQ to the memory devices MEM of the second electronic device 320. The memory devices MEM of the second electronic device 320 may capture the data signal DQ in synchronization with the data strobe signal DQS. The memory devices MEM of the second electronic device 320 may transmit the data strobe signal DQS and the data signal DQ to the first electronic device 310. The first electronic device 310 may capture the data signal DQ in synchronization with the data strobe signal DQS.

In implementations, the pads PD described with reference to FIGS. 1 to 13 may be pads for transmitting the data signal DQ. The transceivers TRC described with reference to FIGS. 1 to 13 may transmit and receive the data signal DQ based on the PAM3. Each of the transceivers TRC may include the first receiver RX1 and the second receiver RX2 extending a margin by performing level conversion for the middle level ML by using strong transistors.

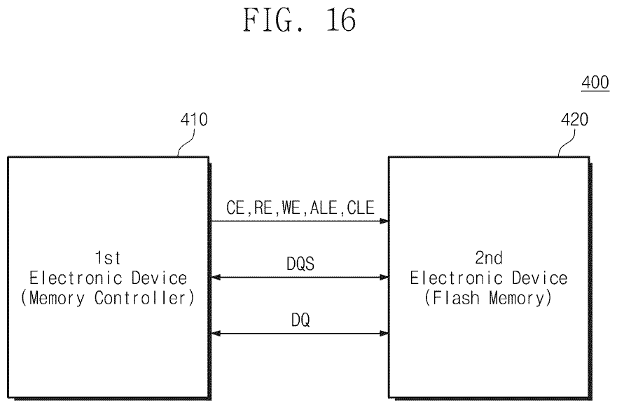

FIG. 16 illustrates an electronic system 400 according to some implementations of the present disclosure. Referring to FIG. 16, the electronic system 400 may include a first electronic device 410 and a second electronic device 420. The first electronic device 410 and the second electronic device 420 may respectively correspond to the first electronic device 110 and the second electronic device 120 described with reference to FIGS. 1 to 13.

In implementations, the first electronic device 410 may be a memory controller. The second electronic device 420 may be a memory device, for example, a flash memory device (e.g., a NAND flash memory device). The first electronic device 410 and the second electronic device 420 may communicate based on the toggle DDR standard. The first electronic device 410 may provide the second electronic device 420 with a chip enable signal CE, a read enable signal RE, a write enable signal WE, an address latch enable signal ALE, a command latch enable signal CLE.

The chip enable signal CE may activate the second electronic device 420. For example, when the second electronic device 420 includes a plurality of flash memory devices, the chip enable signal CE may activate at least one of the plurality of flash memory devices. The read enable signal RE may be used for the second electronic device 420 to generate the data strobe signal DQS. The address latch enable signal ALE may indicate that a signal transmitted through the data signal DQ is an address. The command latch enable signal CLE may indicate that a signal transmitted through the data signal DQ is a command.

The first electronic device 410 and the second electronic device 420 may communicate the data strobe signal DQS. For example, the first electronic device 410 may generate the data strobe signal DQS so as to be transmitted to the second electronic device 420, and the second electronic device 420 may generate the data strobe signal DQS from the read enable signal RE so as to be transmitted to the first electronic device 410. The waveform of the data strobe signal DQS which the second electronic device 420 transmits to the first electronic device 410 may be in a delayed shape of the waveform of the read enable signal RE. The read enable signal RE and the data strobe signal DQS may include an interval where a signal toggles and an interval where a signal does not toggle.

The first electronic device 410 and the second electronic device 420 may communicate the data signal DQ in synchronization with the data strobe signal DQS. For example, the first electronic device 410 may transmit the data strobe signal DQS and the data signal DQ to the second electronic device 420. The second electronic device 420 may capture the data signal DQ in synchronization with the data strobe signal DQS. The second electronic device 420 may transmit the data strobe signal DQS and the data signal DQ to the first electronic device 410. The first electronic device 410 may capture the data signal DQ in synchronization with the data strobe signal DQS.

In implementations, the pads PD described with reference to FIGS. 1 to 13 may be pads for transmitting the data signal DQ. The transceivers TRC described with reference to FIGS. 1 to 13 may transmit and receive the data signal DQ based on the PAM3. Each of the transceivers TRC may include the first receiver RX1 and the second receiver RX2 extending a margin by performing level conversion for the middle level ML by using strong transistors.

In the above implementations, components according to the present disclosure are described by using the terms “first”, “second”, “third”, etc. However, the terms “first”, “second”, “third”, etc. may be used to distinguish components from each other and do not limit the present disclosure. For example, the terms “first”, “second”, “third”, etc. do not involve an order or a numerical meaning of any form.

In the above implementations, components according to implementations of the present disclosure are referenced by using blocks. The blocks may be implemented with various hardware devices, such as an integrated circuit, an application specific IC (ASIC), a field programmable gate array (FPGA), and a complex programmable logic device (CPLD), firmware driven in hardware devices, software such as an application, or a combination of a hardware device and software. Also, the blocks may include circuits implemented with semiconductor elements in an integrated circuit, or circuits enrolled as an intellectual property (IP).

According to implementations of the present disclosure, a margin for determining a signal at a receiver of an electronic device increases. Also, according to implementations of the present disclosure, a constant current of the receiver of the electronic device is reduced. Accordingly, an electronic device performing communication with improved reliability and a reduced power, an operating method of the electronic device, and an electronic system including electronic devices are provided.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. An electronic device comprising:
a transmitter configured to transmit a transmission signal to an external electronic device through a pad;
a first receiver configured to receive a reception signal from the external electronic device through the pad;
a second receiver configured to receive the reception signal from the external electronic device through the pad; and
an output circuit configured to determine data included in the reception signal, based on an output of the first receiver and an output of the second receiver.

2. The electronic device of claim 1, wherein the first receiver is configured to output a logic high indicating a low level or a logic low indicating a middle level and a high level based on the reception signal, and
wherein the second receiver is configured to output a logic high indicating the high level and the middle level or a logic low indicating the low level based on the reception signal.

3. The electronic device of claim 2, wherein a first margin with which the first receiver outputs the logic low is greater than a second margin with which the first receiver outputs the logic high.

4. The electronic device of claim 3, wherein a third margin with which the second receiver outputs the logic high is greater than a fourth margin with which the second receiver outputs the logic low.

5. The electronic device of claim 3, wherein the output circuit is configured to:
determine whether the received data correspond to the high level, the low level, or the middle level, based on a determination result of the first receiver and a determination result of the second receiver.

6. The electronic device of claim 1, wherein the first receiver includes:
a first transistor and a second transistor connected between a power node and a ground node; and
a first resistor connected between a first node between the first transistor and the second transistor and the pad, and
wherein a gate of the first transistor and a gate of the second transistor are connected to the pad.

7. The electronic device of claim 6, wherein a size of the second transistor is larger than a size of the first transistor.

8. The electronic device of claim 6, wherein the first receiver further includes:
a first comparator configured to compare a voltage of the first node and a first reference voltage and to transfer a comparison result to the output circuit.

9. The electronic device of claim 8, wherein the first reference voltage is in the range corresponding to a voltage in a range from a power supply voltage toa half level of a power supply voltage, and wherein the first reference voltage is closer to the half level of the power supply voltage.

10. The electronic device of claim 8, wherein the second receiver includes:
a third transistor and a fourth transistor connected between the power node and the ground node;
a second resistor connected between a second node between the third transistor and the fourth transistor and the pad; and
a second comparator configured to compare a voltage of the second node and a second reference voltage and to transfer a comparison result to the output circuit, and
wherein a gate of the third transistor and a gate of the fourth transistor are connected to the pad.

11. The electronic device of claim 10, wherein a size of the third transistor is larger than a size of the fourth transistor.

12. The electronic device of claim 10, wherein the second reference voltage is in a range from a half level of a power supply voltage to voltage ground level, and wherein the second reference voltage is closer to the half level of the power supply voltage.

13. The electronic device of claim 6, wherein the first transistor includes:
a first inverting transistor and a first calibration transistor connected between the first node and the power node; and
a second inverting transistor and a second calibration transistor connected between the first node and the power node to be parallel to the first inverting transistor and the first calibration transistor,
wherein a gate of the first inverting transistor and a gate of the second inverting transistor are connected to the pad, and
wherein a gate of the first calibration transistor and a gate of the second calibration transistor are controlled by a code.

14. The electronic device of claim 6, wherein the second transistor includes:
a first inverting transistor and a first calibration transistor connected between the first node and the ground node; and
a second inverting transistor and a second calibration transistor connected between the first node and the ground node to be parallel to the second inverting transistor and the second calibration transistor,
wherein a gate of the first inverting transistor and a gate of the second inverting transistor are connected to the pad, and
wherein a gate of the first calibration transistor and a gate of the second calibration transistor are controlled by a code.

15. The electronic device of claim 1, wherein the output circuit is configured to:
receive a first bit from the first receiver;
receive a second bit from the second receiver; and
determine the data based on a pattern of the first bit and the second bit.

16. An operating method of an electronic device which includes a first receiver and a second receiver and is configured to communicate with an external electronic device, the method comprising:
receiving a signal from the external electronic device;
comparing, at the first receiver, the received signal with a first reference voltage;
comparing, at the second receiver, the received signal with a second reference voltage; and
determining whether data of the received signal correspond to a high level, a low level, or a middle level, based on a comparison result of the first receiver and a comparison result of the second receiver.

17. The method of claim 16, wherein comparing the received signal with the first reference voltage includes:
decreasing, at the first receiver, a voltage of the middle level of the received signal; and
comparing a signal having a middle-level voltage being decreased, with the first reference voltage.

18. The method of claim 16, wherein comparing the received signal with the second reference voltage includes:
increasing, at the second receiver, a voltage of the middle level of the received signal; and
comparing a signal having a middle-level voltage being increased, with the second reference voltage.

19. The method of claim 16, wherein determining whether the data of the received signal correspond to any one of the high level, the low level, and the middle level includes:
when the comparison result of the first receiver and the comparison result of the second receiver indicate a logic high, determining the high level;
when the comparison result of the first receiver and the comparison result of the second receiver indicate a logic low, determining the low level; and
when the comparison result of the first receiver and the comparison result of the second receiver indicate different logic levels, determining the middle level.

20. An electronic device comprising:
a transmitter configured to transmit a transmission signal to an external electronic device through a pad;
a first receiver configured to receive a reception signal from the external electronic device through the pad;
a second receiver configured to receive the reception signal from the external electronic device through the pad; and
an output circuit configured to determine data received through the reception signal, based on an output of the first receiver and an output of the second receiver,
wherein each of the first receiver and the second receiver includes:
a first transistor and a second transistor connected between a power node and a ground node; and
a first resistor connected between a first node between the first transistor and the second transistor and the pad,
wherein a gate of the first transistor and a gate of the second transistor are connected to the pad, and
wherein a size of the first transistor is different from a size of the second transistor.
